(19) United States
(12) Patent Application Publication
(10) Pub. No.: US 2012/0200981 A1
(43) Pub. Date: Aug. 9, 2012

(54) ELECTROSTATIC CHUCK AND METHOD FOR REMOVING REMAINING CHARGES THEREON

(75) Inventor: Baohui Zhang, Beijing (CN)

(73) Assignee: BEIJING NMC CO., LTD., Beijing (CN)

(21) Appl. No.: 13/501,169

(22) PCT Filed: Aug. 19, 2010
(86) PCT No.: PCT/CN2010/076158

§ 371 Date: Apr. 10, 2012

(30) Foreign Application Priority Data
Oct. 12, 2009 (CN) 200910235680.4

(51) Int. Cl. H05F 3/00; H01L 21/687

(52) U.S. Cl. 361/212; 361/234

(57) ABSTRACT

The present invention provides an electrostatic chuck, which includes a base (102) and an electrode (401, 402) arranged inside the base, the electrostatic chuck further includes a charge releasing unit, the electrode can be selectively connected to a power supply arranged outside the electrostatic chuck or connected to the charge releasing unit in order to connect to the power supply to obtain electric energy during the process and connect to the charge releasing unit to release remaining charges on the electrode and then to remove remaining charges on the work piece held on the electrostatic chuck during the charge releasing process. A method for removing remaining charges on the electrostatic chuck is also provided, and the method can release the remaining charges on the electrode and the wafer more thoroughly and rapidly to eliminate the appearance of wafer adherence and wafer crack, so as to reduce possibility of the interruption of the process and improve the production efficiency and yield.

### FIELD OF THE INVENTION

The present invention relates to the field of semiconductor fabrication, and particularly relates to an electrostatic chuck holding a wafer in a reaction chamber and a method for removing remaining charges on the electrostatic chuck.

### BACKGROUND OF THE INVENTION

For over half a century from the first transistor coming out, the semiconductor technology has influenced people's lives in various fields, promoted the development of human being's civilization, and created an incredibly huge industry. Miniaturization and low power consumption of the integrated circuits increase the demand for semiconductor. However, as capital input increasing, problems such as development costs and manufacturing costs of the process for integrated circuits become more and more predominant. So, increasing efficiency and reducing cost have become a problem concerned by the manufacturing company.

Generally, a fabrication procedure for integrated circuits is a highly automatic pipelining procedure, most of the manufacturing processes (for example, etching process, physical vapor deposition, chemical vapor deposition, etc.) are completed in a reaction chamber, and a preceding process is very close to a subsequent process, so whether respective processes can be performed successfully will directly influence the production efficiency of the entire procedure. Moreover, when a semiconductor device such as a wafer is processed in the reaction chamber, a mechanical chuck and a vacuum chuck are usually required to hold the wafer. However, the phenomenon of wafer crack often occurs due to pressure or collision when the wafer is held by the mechanical chuck or the vacuum chuck, thereby resulting in the interruption of the entire procedure and contamination, and influencing production efficiency and yield.

So, an electrostatic chuck was designed to hold the wafer. The electrostatic chuck holds the wafer on it by electrostatic attraction, thus reducing the phenomenon of wafer crack, increasing effective processing area of the wafer and reducing deposition of corrosion particles on the surface of the wafer. FIG. 1 shows a working principle diagram of a conventional electrostatic chuck. As shown in FIG. 1, the electrostatic chuck is connected to a power supply outside the electrostatic chuck, and includes a base 102 and two electrodes 401, 402 arranged in the base 102. The electrodes 401, 402 are packaged by insulating layers and are connected to two terminals of the power supply, wherein, the first electrode 401 is connected to the negative terminal of the power supply, and the second electrode 402 is connected to the positive terminal of the power supply, and the power supply is a DC power supply. A wafer ejector pin 103 is arranged at a central position of the base 102, to move upward during leaving the base in order to lift up the wafer 101 arranged on the top of the base 102, so that the manipulator can take the wafer 101 away; or to move downward during entering the base in order to place the wafer 101 from the manipulator on the top of the base 102.

During a practical manufacturing process, the wafer 101 is first placed on the top of the electrostatic chuck 102; then the electrodes 401, 402 are connected to the power supply to make negative charges accumulate on the first electrode 401 and positive charges accumulate on the second electrode 402, thereby these charges will induce positive charges and negative charges in areas corresponding to the electrodes 401, 402 on the wafer 101, respectively. An electrostatic field is generated between a respective electrode in a corresponding area and the wafer 101 by the charges with opposite polarities produced by the electrode and the wafer 101, and the wafer 101 is firmly absorbed onto the surface of the electrostatic chuck by the electrostatic attraction of the electrostatic field; then, the manufacturing process is performed on the wafer 101 and the wafer 101 is taken away by the manipulator after the process is finished.

As mentioned above, the wafer 101 is absorbed onto the surface of the electrostatic chuck by means of the electrostatic attraction between the wafer 101 and the electrostatic chuck. However, it is well known that inductive charges on the wafer 101 must be removed after the manufacturing process is finished so that the wafer 101 can leave the base successfully. A method for removing the inductive charges on the wafer 101, which is usually used, is as follows: after the manufacturing process is finished, a voltage with a polarity opposite to that of the voltage used in the manufacturing process is applied on the electrodes 401, 402, that is, a positive voltage is applied on the first electrode 401 and a negative voltage is applied on the second electrode 402, so that charges with a polarity opposite to the polarity of charges on the wafer 101 during the manufacturing process are induced on the wafer 101 so as to neutralize the charges on the wafer 101 induced during the preceding manufacturing process. In other words, a voltage with a polarity opposite to that of the voltage applied during the manufacturing process is applied to the two electrodes 401, 402 of the electrostatic chuck, so as to release electrostatic charges on the wafer 101. After the electrostatic charges are released, the wafer 101 is lifted up by the wafer ejector pin 103 to wait for the manipulator to take it away.

However, in practical applications, electrostatic charges on the electrodes and the wafer cannot be removed completely by the way of applying a reverse voltage as mentioned-above. This is because elimination of the electrostatic charges is usually influenced by many factors, such as process conditions, amplitude of the reverse voltage, time of applying the reverse voltage etc. So, when the above method is used to remove the electrostatic charges on the electrodes and the wafer, it is difficult to overcome the influences of the above factors, thus it is difficult to remove the electrostatic charges more thoroughly. Furthermore, the remaining charges existing on the electrodes and the wafer will result in wafer adherence and cause the wafer to deviate or fall down when the ejector pin is lifted up, so that the manipulator cannot take the wafer away. Moreover, the more the remaining charges are, the more serious the phenomenon of wafer adherence is, so that when the phenomenon of adherence is very serious the phenomenon of wafer crack will occur, thus influencing smoothness of the manufacturing procedure.

To this end, persons skilled in the art try to obtain the corresponding relationships between various parameters of the process and the reverse voltage by a lot of experiments and desire to eliminate the remaining charges on the electrodes and the wafer thoroughly. But, in practical applications, this method not only increases the complexity of the apparatus and elongates the production period, but also cannot remove the remaining charges thoroughly. So, currently it is desirable for the persons skilled in the art to provide a method and an apparatus which can remove the remaining charges on the electrodes and the wafer more thoroughly.

### SUMMARY OF THE INVENTION

To solve the problems mentioned above, the present invention provides an electrostatic chuck and a method for removing remaining charges on the electrostatic chuck, which can remove remaining charges on the wafer and electrodes arranged in the electrostatic chuck more thoroughly and quickly, thereby eliminating phenomenon of wafer adherence and wafer crack, preventing the process from being interrupted, and improving the production efficiency and yield.

To this end, the present invention provides an electrostatic chuck which includes a base and an electrode arranged inside the base, the electrostatic chuck further includes a charge releasing unit, the electrode is selectively connected to a power supply arranged outside the electrostatic chuck or the charge releasing unit, to connect to the power supply so as to obtain electrical energy during a manufacturing process and to connect to the charge releasing unit during a charge releasing process so as to release remaining charges on the electrode, and thus remove remaining charges on a work piece held on the electrostatic chuck.

Wherein, the charge releasing unit is a grounded circuit, and the electrode is connected to the grounded circuit to constitute a path for releasing remaining charges during the charge releasing process.

Wherein, the number of the electrode is two, each of the two electrodes can be selectively connected to the power supply or the charge releasing unit.

Wherein, the charge releasing unit includes a resistor, and the resistor is connected between the two electrodes to constitute a charge releasing loop during the charge releasing process.

Wherein, a selection switch is among the electrode, the power supply and the charge releasing unit, the electrode is connected to a moving contact of the selection switch, and the power supply and the charge releasing unit are connected to two static contacts of the selection switch respectively, so that the electrode can be selectively connected to the power supply or the charge releasing unit by the moving contact being selectively connected to one of the two static contacts or the other. Since the structure of the selection switch is simple and the operation of the selection switch is simple, providing such a selection switch between on one hand the electrode, and the other hand the power supply or the charge releasing unit can make the electrostatic chuck have a compact structure and nice appearance, in addition to make the electrode be selectively connected to the power supply or the charge releasing unit.

As another technical solution, the present invention further provides a method for removing remaining charges on an electrostatic chuck. The electrostatic chuck includes a base, a charge releasing unit and an electrode arranged inside the base, the method includes steps: 1) during a manufacturing process, placing a work piece on the base, connecting the electrode to a power supply, absorbing the work piece onto the electrostatic chuck by electrostatic attraction between the electrode and the work piece, and performing the manufacturing process; 2) after the manufacturing process is finished, applying an inverse voltage with a polarity opposite to that applied in the step 1) on the electrode, to neutralize charges on the electrode and the work piece generated during the manufacturing process; 3) disconnecting the electrode from the power supply, and connecting the electrode to a charge releasing unit to remove remaining charges on the electrode, thus removing remaining charges on the work piece held on the electrostatic chuck.

Wherein, the amplitude of the inverse voltage applied in the step 2) is 500V to 2000V and time for applying the inverse voltage is 2 s to 6 s, preferably 3 s or 5 s.

Wherein, the charge releasing unit is a grounded circuit, and in the step 3) the electrode is connected to the grounded circuit to constitute a path for releasing charges so as to release remaining charge on the electrode.

Wherein, the number of the electrode is two, the charge releasing unit includes a resistor, and in the step 3), the resistor is connected between the two electrodes to constitute a loop for releasing charges to release remaining charges on the electrodes.

Wherein, the resistance of the resistor is 5000 Ω to 10 MΩ, preferably 1 MΩ to 2 MΩ.

Wherein, in the step 3), the electrode is connected to the charge releasing unit for 0.5 s to 10 s.

The present invention has the following advantageous effects.

Since the electrostatic chuck provided by the present invention has the charge releasing unit, remaining charges on the electrode inside the electrostatic chuck and the wafer held on the electrostatic chuck can be released more thoroughly and rapidly through the charge releasing unit, thereby eliminating the phenomenon of wafer adherence and wafer crack resulted from the existing remaining charges, so as to prevent the process from being interrupted. So, the electrostatic chuck provided by the present invention improves the reliability of the apparatus and increases production yield; and shortens the time used to release the remaining charges on the electrostatic chuck and increases the production efficiency.

Similarly, in the method for removing remaining charges on the electrostatic chuck provided by the present invention, the remaining charges on the electrode inside the electrostatic chuck and the wafer held on the electrostatic chuck can be released more thoroughly and rapidly through the charge releasing unit. So, the method for removing remaining charges on the electrostatic chuck provided by the present invention can eliminate the phenomenon of wafer adherence and wafer crack conveniently and rapidly, and can prevent the process from being interrupted, thereby improves the reliability of the apparatus and increases production yield; and the method can shorten the time used to release the remaining charges on the electrostatic chuck, thus increasing the production efficiency.

### BRIEF DESCRIPTION OF THE DRAWINGS

FIG. 1 is a working principle diagram of a conventional electrostatic chuck;

FIG. 2 is a schematic view of a structure of an electrostatic chuck provided by the present invention; and

FIG. 3 is a schematic view of a structure of another electrostatic chuck provided by the present invention.

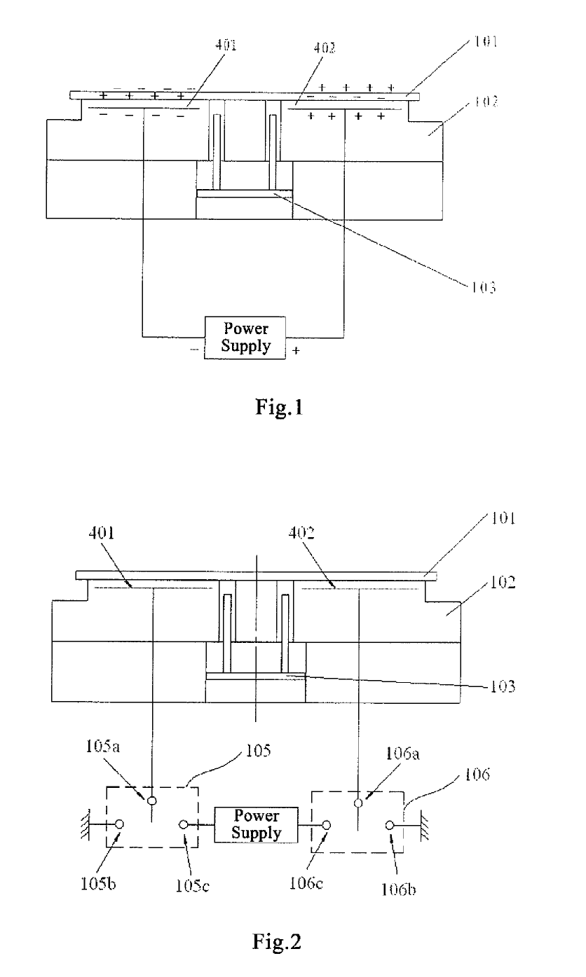

In the Figures: 101—wafer 102—base 103—wafer ejector pin 401—first electrode 402—second electrode 105—first switcher 105a—moving contact 105b—first static contact 106—second switcher 106a—moving contact 106b—first static contact 106c—second static contact R-resistor

### DETAILED DESCRIPTION OF THE PREFERRED EMBODIMENTS

In order to enable the persons skilled in the art better understand the technical solutions of the present invention, the electrostatic chuck and the method for removing remaining charges on the electrostatic chuck provided by the present invention will be described in detail below, in connection with the figures.

The electrostatic chuck of the present invention includes a base, an electrode arranged inside the base and a charge releasing unit. The electrode is selectively connected to a power supply arranged outside the electrostatic chuck or connected to the charge releasing unit. During a manufacturing process, the electrode is connected to the power supply to obtain electrical energy; during a charge releasing process, the electrode is connected to the charge releasing unit to release remaining charges on the electrode, so as to remove remaining charges on the work piece held on the electrostatic chuck. Wherein, the charge releasing unit can take forms of a grounded circuit and/or a resistor loop, and eliminate the remaining charge on the electrode and the wafer by means of the grounded circuit and/or the resistor loop. An electrostatic chuck provided with the charge releasing unit in the form of the grounded circuit or the resistor loop will be described below in detail, respectively.

### Embodiment 1

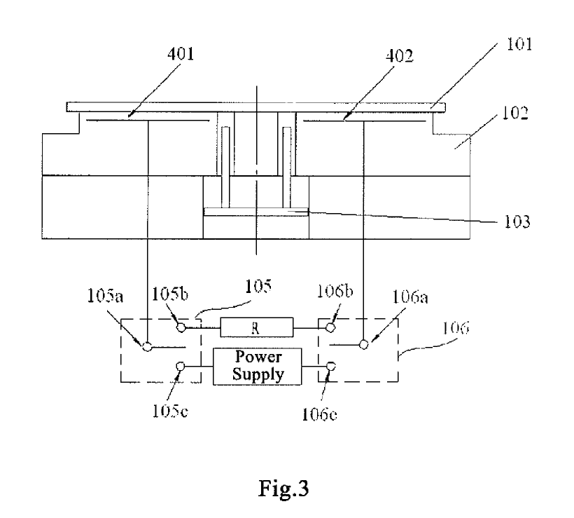

Referring to FIG. 2, FIG. 2 is a schematic view of a structure of an electrostatic chuck provided by the first embodiment of the present invention. As shown in the figure, the charge releasing unit in the present embodiment takes the form of the grounded circuit to eliminate remaining charges on the electrodes and the wafer. The electrostatic chuck of the present embodiment includes a base 102, two electrodes 401, 402 (of course, the electrostatic chuck may also be provided with only one electrode), and two switchers 105, 106 (the switchers are the parts within the frames of dotted lines, and the same with the following FIG. 3). The two electrodes 401, 402 which are separated from each other are arranged inside the base 102, are packaged by an insulating layer (not shown in the Figure), and the two electrodes 401, 402 are connected to the two switchers 105, 106 arranged outside the base 102, respectively. A path is arranged in the middle of the base 102 to pass through the base 102, and a wafer ejector pin can move up and down through the path.

Each of the switchers 105, 106 in the present embodiment has three contacts, one moving contact and two static contacts. Wherein, as for the first switcher 105, its moving contact 105a is connected to the first electrode 401, its first static contact 105b is connected to the ground, and its second static contact 105c is connected to the positive terminal of the power supply; as for the second switcher 106, its moving contact 106a is connected to the second electrode 402, its first static contact 106b is connected to the ground, and its second static contact 106c is connected to the negative terminal of the power supply. The power supply is a high-voltage DC power supply and is arranged outside the base 102.

With the above design of the electrostatic chuck, the following operations can be achieved conveniently:

During the manufacturing process, the moving contact 105a of the first switcher 105 is adjusted so as to be connected to the second static contact 105c of the first switcher 105 while the moving contact 106a of the second switcher 106 is adjusted so as to be connected to the second static contact 106c of the second switcher 106; at this time the power supply supplies power to the electrodes 401, 402 so that electrostatic attraction is generated between the electrodes 401, 402 and the wafer 101 and the electrostatic chuck begins to work. The principle of generating electrostatic attraction is the same as that in the background of the invention and the description thereof is omitted.

After the manufacturing process is finished, when remaining charges are released, the moving contact 105a of the first switcher 105 is adjusted once again so as to be connected to the first static contact 105b of the first switcher 105 while the moving contact 106a of the second switcher 106 is adjusted so as to be connected to the first static contact 106b of the second switcher 106; at this time each of the electrodes 401, 402 is connected to the ground to constitute a path for releasing charges, respectively. By the respective paths for releasing charges, the remaining charges on the electrodes 401, 402 are released, thus the remaining charges on the wafer 101 are eliminated.

In the present embodiment, the electrodes 401, 402 can be selectively connected to the power supply or the ground conveniently by the switchers 105, 106, which is a simple operation and will not increase the complexity of the process.

### Embodiment 2

An electrostatic chuck provided by the second embodiment of the present invention is shown in FIG. 3. The charge releasing unit in the present embodiment includes a resistor R, which is used to connect the two electrodes 401, 402 together to constitute a loop for releasing charges. In addition, other structures of the electrostatic chuck in the present embodiment are all the same as those of the electrostatic chuck in the first embodiment. In the following, differences of the second embodiment from the first embodiment will be described.

In the present embodiment, two terminals of the resistor R are connected to the first static contact 105b of the first switcher 105 and the first static contact 106b of the second switcher 106, respectively, that is, compared with the first embodiment, in the present embodiment, static contacts of the first switcher 105 and the second switcher 106 are connected to the resistor R instead of to the ground. Thus, the first electrode 401 and the second electrode 402 respectively use the first switcher 105 and the second switcher 106 to be selectively connected to the power supply or the resistor R.

When remaining charges are released, the moving contact 105a of the first switcher 105 is adjusted so as to be connected to the first static contact 105b of the first switcher 105, while the moving contact 106a of the second switcher 106 is adjusted so as to be connected to the first static contact 106b of the second switcher 106. So, the first electrode 401 and the second electrode 402 are connected by the resistor R to constitute a loop for releasing charges, and the remaining charges on the electrodes 401, 402 are released by the resistor R, thereby eliminating remaining charges on the wafer 101.

It should be noted that in practical applications the charge releasing unit may be entirely arranged inside the base 102, for example, the first switcher 105, the second switcher 106 and the resistor R in the above second embodiment are arranged inside the base 102, only a knob or a sliding block connected to the first switcher 105 and the second switcher 106 respectively is arranged on the surface of the base 102, and the resistor R acting as the charge releasing unit inside the base 102 is connected to or disconnected from the contacts of the first and second switchers through turning the knob or moving the sliding block. Of course, part or the whole of the charge releasing unit may be arranged outside the base 102, for example, the first switcher 105 and the second switcher 106 are arranged inside the base 102, the resistor R in the second embodiment is arranged outside the base 102, and connecting terminals connected to the static contacts 105b and 106b respectively are arranged on the surface of the base 102, so that the resistor R outside the base 102 can be connected to the static contacts 105b and 106b only by connecting to the connecting terminals, and the electrodes are selectively connected to the power supply or the resistor acting as the charge releasing unit through actions of the moving contacts of the first switcher 105 and the second switcher 106; as another example, the first switcher 105 and the second switcher 106 are arranged inside the base 102, connecting terminals connected to the static contacts 105b and 106b respectively are arranged on the surface of the base 102 and the connecting terminals are connected to the ground, so that the static contacts 105b and 106b can be connected to the ground, and the electrodes can be selectively connected to the power supply or the grounded circuit as the charge releasing unit through actions of the moving contacts of the first switcher 105 and the second switcher 106.

It should be further pointed out that wherever the charge releasing unit is arranged inside or outside the base of the electrostatic chuck, as long as the electrostatic chuck is provided with the charge releasing unit by which remaining charges on the electrodes and the wafer can be more thoroughly and rapidly eliminated, all these should be considered within the protection scope of the present invention. That is, the electrostatic chuck provided by the present invention is not limited to a case in which the charge releasing unit is arranged inside the base, but includes a case in which part or the whole of the charge releasing unit is arranged outside the base.

It should be further pointed out that in practical applications the electrodes of the electrostatic chuck can be selectively connected to the charge releasing unit or connected to the power supply arranged outside the electrostatic chuck in a manual manner or in an automatic manner. When the automatic manner is used, for example, by executing a preset program, the electrodes can be automatically disconnected from the power supply and then connected to the charge releasing unit after every manufacturing process is finished, thereby entering into the charge releasing process to release remaining charges on the electrodes, and further remove remaining charges on the work piece held on the electrostatic chuck.

In addition, the present invention further provides a method for removing remaining charges on an electrostatic chuck, which removes remaining charges on a wafer and electrodes inside a base using a charge releasing unit included in the electrostatic chuck, to prevent phenomenon of wafer adherence and wafer crack from occurring, thereby reducing possibility of the interruption of the process and increasing production efficiency.

The method for removing remaining charges on the electrostatic chuck provided by the present invention includes steps:
1) During a manufacturing process, placing a wafer on the base, adjusting switchers so that electrodes are connected to a power supply, absorbing the wafer onto the base of the electrostatic chuck by electrostatic attraction between the electrodes and the wafer, and then performing the manufacturing process on the wafer.
2) After the manufacturing process is finished, reversing the polarity of the power supply, and applying an inverse voltage of 500V to 2000V with a polarity opposite to that of the voltage applied in the step 1) for 2 s to 6 s, preferably, 3 s and 5 s, so as to neutralize charges on the electrodes and the wafer generated in the step 1).
3) Adjusting moving contacts of the switchers to make the electrodes be connected to a charge releasing unit, release remaining charges on the electrodes and then release remaining charges on the wafer. When the charge releasing unit is a grounded circuit, the electrodes are connected to the grounded circuit for 0.5 s to 10 s, for example, 1 s or 2 s; when the charge releasing unit is a loop constituted by a resistor, the resistance of the resistor should be 50000-10M0, preferably 1 MΩ-2 MΩ, and the electrodes are connected to the loop constituted by the resistor for 0.5 s-10 s, for example, 1 s or 2 s.

In sum, the electrostatic chuck and the method for removing remaining charges on the electrostatic chuck provided by the present invention use the charge releasing unit to release remaining charges on the electrodes and the wafer more thoroughly and rapidly, eliminating the phenomenon of wafer adherence and wafer crack, thus preventing the process from being interrupted and increasing the production efficiency. The method for removing remaining charges provided by the present invention is simple to operate, convenient and easy to implement.

It should be understood that the embodiments mentioned above are exemplary embodiments used to describe the inventive principle. However, the present invention is not limited thereto. It is obvious to those skilled in the art that various modifications and improvements can be made without departing from the spirit and principle of the present invention, and thus all the modifications and improvements are considered to be within the scope of the invention.

What is claimed is:

1. An electrostatic chuck, including a base and an electrode arranged inside the base, characterized in that,
the electrostatic chuck further includes a charge releasing unit, the electrode is selectively connected to a power supply arranged outside the electrostatic chuck or the charge releasing unit, to connect to the power supply so as to obtain electrical energy during a manufacturing process and to connect to the charge releasing unit during a charge releasing process so as to release remaining charges on the electrode, and thus remove remaining charges on a work piece held on the electrostatic chuck.

2. The electrostatic chuck according to claim 1, characterized in that, the charge releasing unit is a grounded circuit, and the electrode is connected to the grounded circuit to constitute a path for releasing charges during the charge releasing process.

3. The electrostatic chuck according to claim 1, characterized in that, the number of the electrode is two, each of the two electrodes can be selectively connected to the power supply or the charge releasing unit.

4. The electrostatic chuck according to claim 3, characterized in that, the charge releasing unit includes a resistor, and the resistor is connected between the two electrodes to constitute a charge releasing loop during the charge releasing process.

5. The electrostatic chuck according to any one of claims 1 to 4, characterized in that, a selection switch is among the electrode, the power supply and the charge releasing unit, the electrode is connected to a moving contact of the selection switch, the power supply and the charge releasing unit are connected to two static contacts of the selection switch respectively, so that the electrode can be selectively connected to the power supply or the charge releasing unit by the moving contact being selectively connected to one of the two static contacts or the other.

6. A method for removing remaining charges on an electrostatic chuck, characterized in that, the electrostatic chuck includes a base, a charge releasing unit and an electrode arranged inside the base, the method includes steps:
1) during a manufacturing process, placing a work piece on the base, connecting the electrode to a power supply, absorbing the work piece onto the electrostatic chuck by electrostatic attraction between the electrode and the work piece, and performing the manufacturing process;
2) after the manufacturing process is finished, applying an inverse voltage with a polarity opposite to that applied in the step 1) on the electrode, to neutralize charges on the electrode and the work piece generated during the manufacturing process;
3) disconnecting the electrode from the power supply, and connecting the electrode to a charge releasing unit to remove remaining charges on the electrode, and thus remove remaining charges on the work piece held on the electrostatic chuck.

7. The method for removing remaining charges on an electrostatic chuck according to claim 6, characterized in that, the amplitude of the inverse voltage applied in the step 2) is 500V to 2000V and time for applying the inverse voltage is 2 s to 6 s.

8. The method for removing remaining charges on an electrostatic chuck according to claim 6, characterized in that, the charge releasing unit is a grounded circuit, and in the step 3), the electrode is connected to the grounded circuit to constitute a path for releasing charges so as to release remaining charge on the electrode.

9. The method for removing remaining charges on an electrostatic chuck according to claim 6, characterized in that, the number of the electrode is two, the charge releasing unit includes a resistor, and in the step 3), the resistor is connected between the two electrodes to constitute a loop for releasing charges so as to release remaining charges on the two electrodes.

10. The method for removing remaining charges on an electrostatic chuck according to claim 9, characterized in that, the resistance of the resistor is 5000 Ω to 10 MΩ.

11. The method for removing remaining charges on an electrostatic chuck according to claim 6, characterized in that, in the step 3), the electrode is connected to the charge releasing unit for 0.5 s to 10 s.
